(19) United States
(12) Patent Application Publication
(10) Pub. No.: US 2024/0313065 A1
(43) Pub. Date: Sep. 19, 2024

(54) SEMICONDUCTOR DEVICE STRUCTURE WITH CONTACT STRUCTURE AND METHOD FOR FORMING THE SAME

(71) Applicant: Taiwan Semiconductor Manufacturing Company, Ltd., Hsinchu (TW)

(72) Inventors: Chun-Yuan CHEN, HsinChu (TW); Huan-Chieh SU, Tianzhong Township (TW); Chih-Hao WANG, Baoshan Township (TW)

(21) Appl. No.: 18/185,558

(22) Filed: Mar. 17, 2023

(51) Int. Cl. H01L 29/40; H01L 29/06; H01L 29/417; H01L 29/423; H01L 29/775

(52) U.S. Cl. CPC H01L 29/401; H01L 29/0673; H01L 29/41775; H01L 29/42392; H01L 29/775

(57) ABSTRACT

A method for forming a semiconductor device structure is provided. The method includes forming a gate stack and a source/drain structure over a substrate. The method includes removing the gate dielectric layer over the first sidewall of the gate electrode. The method includes forming a dielectric layer over the source/drain structure and the substrate. The gate stack is embedded in the dielectric layer. The method includes forming a contact structure in the dielectric layer and over the source/drain structure, wherein a first top surface of the contact structure is substantially level with a second top surface of the gate electrode.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 is a perspective view of a semiconductor device structure, in accordance with some embodiments.

FIGS. 2A-2F are cross-sectional views of various stages of a process for forming a semiconductor device structure, in accordance with some embodiments.

FIGS. 3A-3G are perspective views of various stages of a process for forming a semiconductor device structure, in accordance with some embodiments.

FIG. 3B-1 is a cross-sectional view illustrating an upper portion of the semiconductor device structure along a sectional line I-I′ in FIG. 3B, in accordance with some embodiments.

FIG. 3C-1 is a cross-sectional view illustrating an upper portion of the semiconductor device structure along a sectional line I-I′ in FIG. 3C, in accordance with some embodiments.

FIG. 3D-1 is a cross-sectional view illustrating an upper portion of the semiconductor device structure along a sectional line I-I′ in FIG. 3D, in accordance with some embodiments.

FIG. 3E-1 is a cross-sectional view illustrating an upper portion of the semiconductor device structure along a sectional line I-I′ in FIG. 3E, in accordance with some embodiments.

FIG. 3G-1 is a cross-sectional view illustrating an upper portion of the semiconductor device structure along a sectional line I-I′ in FIG. 3G, in accordance with some embodiments.

FIG. 3G-2 is a cross-sectional view illustrating an upper portion of the semiconductor device structure along a sectional line II-II′ in FIG. 3G, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure form a semiconductor device structure with FinFETs. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. Source/drain structure(s) may refer to a source or a drain, individually or collectively dependent upon the context.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

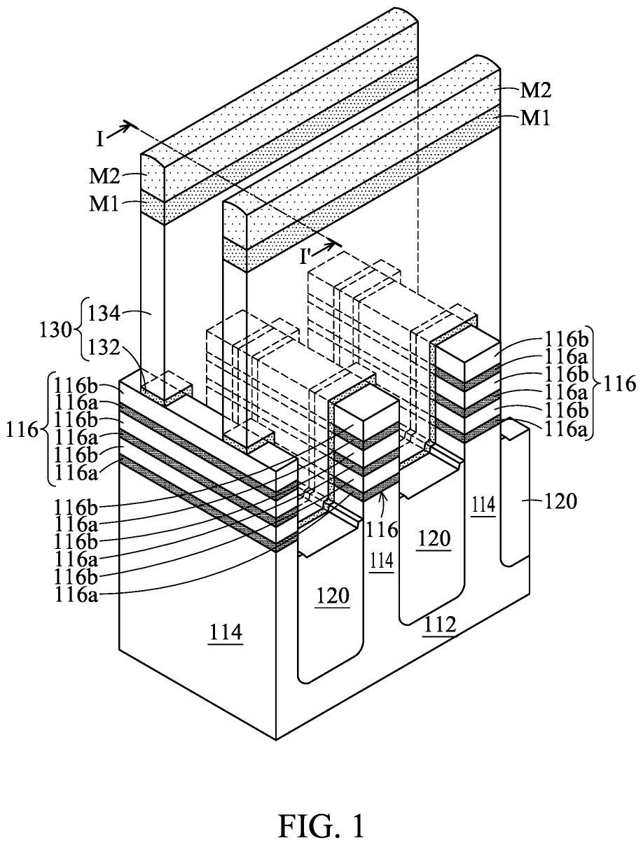

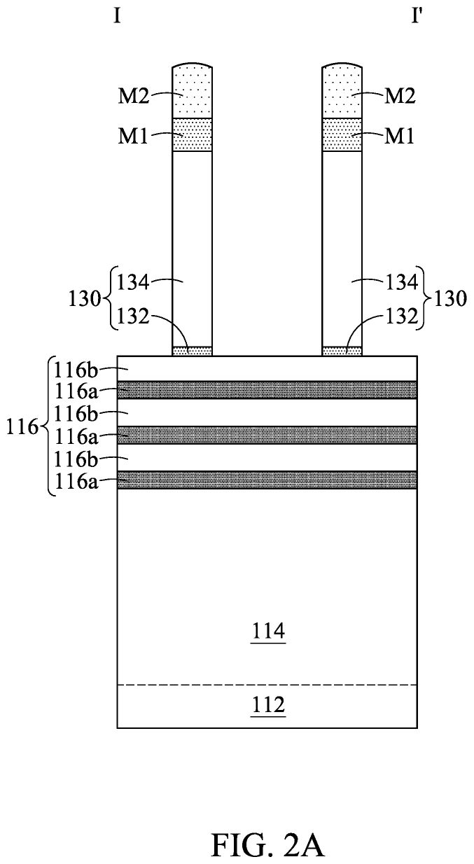

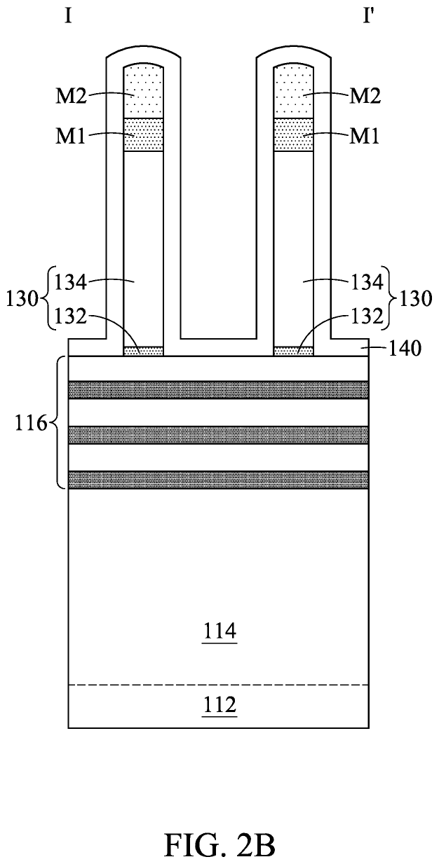

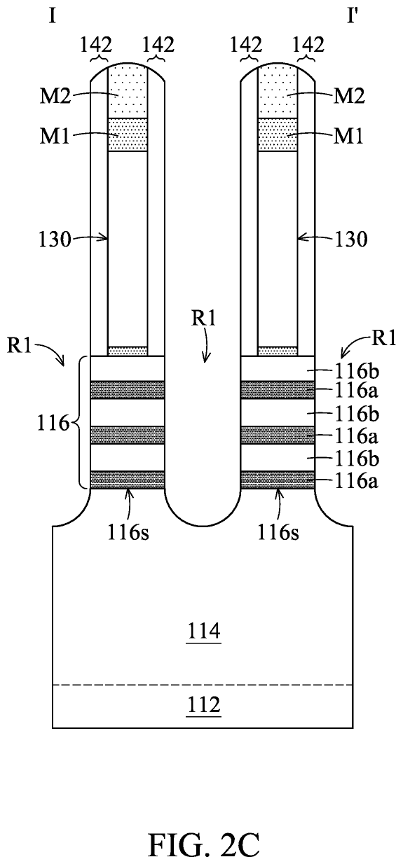

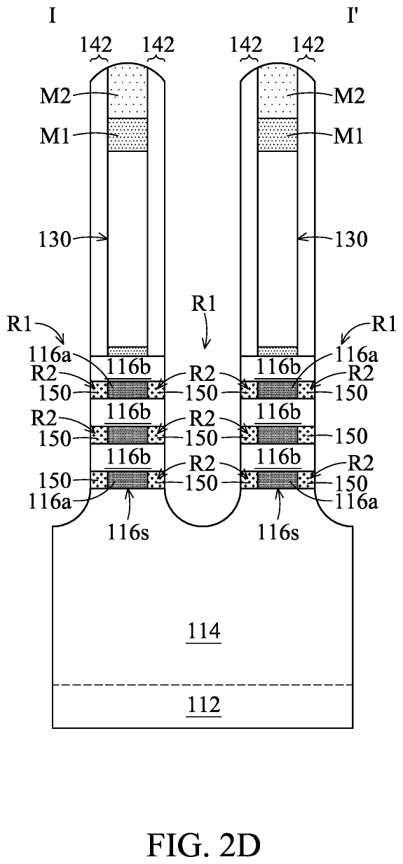

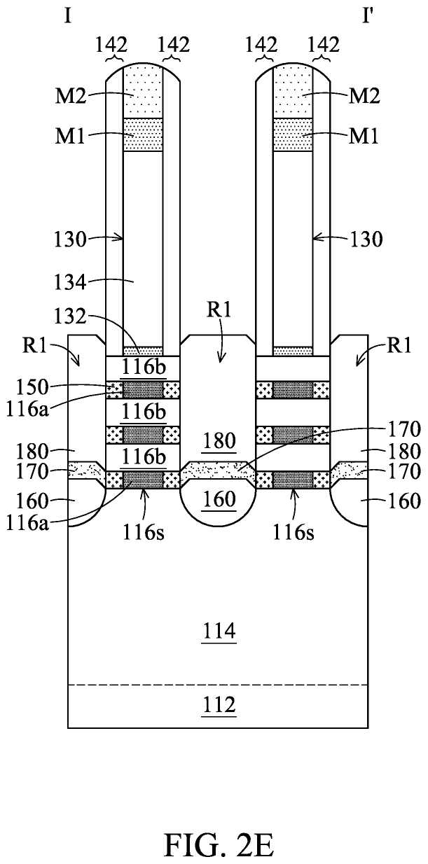

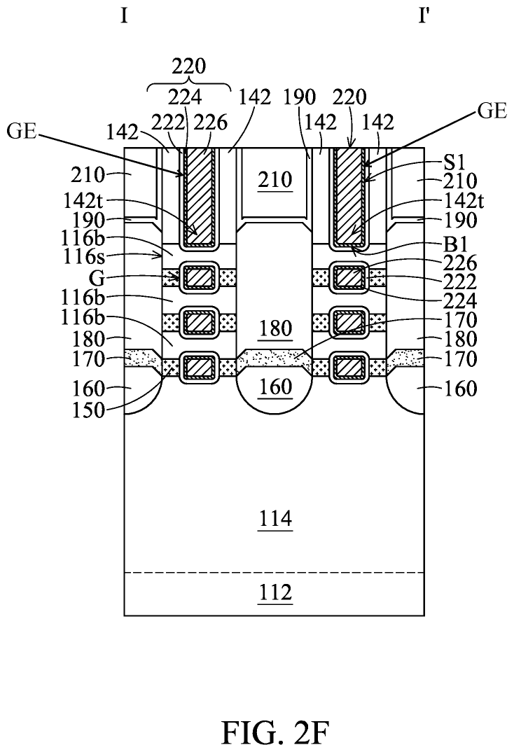

FIG. 1 is a perspective view of a semiconductor device structure, in accordance with some embodiments. FIG. 2A is a cross-sectional view illustrating the semiconductor device structure along a sectional line I-I′ in FIG. 1, in accordance with some embodiments.

As shown in FIGS. 1 and 2A, a substrate 112, fins 114, and multilayer stacks 116 are provided, in accordance with some embodiments. The substrate 112 includes, for example, a semiconductor substrate. The semiconductor substrate includes, for example, a semiconductor wafer (such as a silicon wafer) or a portion of a semiconductor wafer. In some embodiments, the substrate 112 is made of an elementary semiconductor material including silicon or germanium in a single crystal, polycrystal, or amorphous structure.

In some other embodiments, the substrate 112 is made of a compound semiconductor, such as silicon carbide, gallium arsenide, gallium phosphide, indium phosphide, and/or indium arsenide, an alloy semiconductor, such as SiGe and/or GaAsP, or a combination thereof. The substrate 112 may also include multi-layer semiconductors, semiconductor on insulator (SOI) (such as silicon on insulator or germanium on insulator), or a combination thereof.

In some embodiments, the substrate 112 is a device wafer that includes various device elements. In some embodiments, the various device elements are formed in and/or over the substrate 112. The device elements are not shown in figures for the purpose of simplicity and clarity. Examples of the various device elements include active devices, passive devices, other suitable elements, or a combination thereof. The active devices may include transistors or diodes (not shown). The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 112. The isolation features are used to define active regions and electrically isolate various device elements formed in and/or over the substrate 112 in the active regions. In some embodiments, the isolation features include shallow trench isolation (STI) features, local oxidation of silicon (LOCOS) features, other suitable isolation features, or a combination thereof.

The fins 114 are over the substrate 112, in accordance with some embodiments. In some embodiments, the fins 114 and the substrate 112 are formed in one piece. The fins 114 and the substrate 112 are made of the same material, in accordance with some embodiments.

In some other embodiments, the fins 114 and the substrate 112 are formed using different processes. The fins 114 and the substrate 112 are made of the same material or different materials, in accordance with some embodiments.

The multilayer stacks 116 are formed over the fins 114 respectively, in accordance with some embodiments. Each multilayer stack 116 includes sacrificial layers 116a and channel layers 116b, in accordance with some embodiments. The sacrificial layers 116a and the channel layers 116b are alternately arranged as illustrated in FIG. 1, in accordance with some embodiments.

It should be noted that, for the sake of simplicity, FIG. 1 shows three layers of the sacrificial layers 116a and three layers of the channel layers 116b for illustration, but does not limit the invention thereto. In some embodiments, the number of the sacrificial layers 116a or the channel layers 116b is between 2 and 10.

The sacrificial layers 116a are made of a first material, such as a first semiconductor material, in accordance with some embodiments. The channel layers 116b are made of a second material, such as a second semiconductor material, in accordance with some embodiments.

The first material is different from the second material, in accordance with some embodiments. The first material has an etch selectivity with respect to the second material, in accordance with some embodiments. In some embodiments, the sacrificial layers 116a are made of SiGe, and the channel layers 116b are made of Si.

In some other embodiments, the sacrificial layers 116a or the channel layers 116b are made of other materials such as germanium, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or a combination thereof.

The channel layers 116b, the fins 114, and the substrate 112 are made of the same material such as Si, and the sacrificial layers 116a and the fins 114 (or the substrate 112) are made of different materials, in accordance with some embodiments.

In some other embodiments, the sacrificial layers 116a, the channel layers 116b, and the fin 114 (or the substrate 112) are made of different materials, in accordance with some embodiments. The sacrificial layers 116a and the channel layers 116b are formed using a molecular beam epitaxy (MBE) process, a metal-organic chemical vapor deposition (MOCVD) process, and/or another suitable epitaxial growth process.

As shown in FIG. 1, a dielectric layer 120 is formed over the substrate 112, in accordance with some embodiments. The dielectric layer 120 surrounds the fins 114, in accordance with some embodiments. The dielectric layer 120 is made of oxide (such as silicon oxide), fluorosilicate glass (FSG), a low-k dielectric material, and/or another suitable dielectric material. The dielectric layer 120 may be formed by an atomic layer deposition (ALD) process, a chemical vapor deposition (CVD) process, or another applicable process.

As shown in FIGS. 1 and 2A, gate stacks 130 and mask layers M1 and M2 are formed over the multilayer stacks 116 and the dielectric layer 120, in accordance with some embodiments. The gate stacks 130 are wrapped around the multilayer stacks 116 and upper portions of the fins 114, in accordance with some embodiments.

Each gate stack 130 includes a gate dielectric layer 132 and a gate electrode 134, in accordance with some embodiments. The gate dielectric layer 132, the gate electrode 134, and the mask layers M1 and M2 are sequentially stacked over the multilayer stacks 116, in accordance with some embodiments.

The gate dielectric layer 132 conformally covers the multilayer stacks 116, the fins 114 and the dielectric layer 120, in accordance with some embodiments. The gate dielectric layer 132 is made of an insulating material, such as oxide (e.g., silicon oxide), in accordance with some embodiments. The gate electrode 134 is made of a semiconductor material (e.g. polysilicon) or a conductive material (e.g., metal or alloy), in accordance with some embodiments.

The formation of the gate dielectric layer 132 and the gate electrode 134 includes: depositing a gate dielectric material layer (not shown) over the multilayer stacks 116, the fins 114, and the dielectric layer 120; depositing a gate electrode material layer (not shown) over the gate dielectric material layer; sequentially forming the mask layers M1 and M2 over the gate electrode material layer, wherein the mask layers M1 and M2 expose portions of the gate electrode material layer; and removing the exposed portions of the gate electrode material layer and the gate dielectric material layer thereunder, in accordance with some embodiments.

In some embodiments, the mask layer M1 serves as a buffer layer or an adhesion layer that is formed between the underlying gate electrode 134 and the overlying mask layer M2. The mask layer M1 may also be used as an etch stop layer when the mask layer M2 is removed or etched.

In some embodiments, the mask layer M1 is made of an oxide-containing insulating material (e.g., silicon oxide), a nitride-containing insulating material (e.g., silicon nitride, silicon oxynitride, silicon oxycarbonitride, or silicon carbonitride), an carbon-containing insulating material (e.g., silicon carbide), or a metal oxide material (e.g., aluminum oxide).

In some embodiments, the mask layer M1 is formed by a deposition process, such as a chemical vapor deposition (CVD) process, a low-pressure chemical vapor deposition (LPCVD) process, a plasma enhanced chemical vapor deposition (PECVD) process, a high-density plasma chemical vapor deposition (HDPCVD) process, a spin-on process, or another applicable process.

In some embodiments, the mask layer M2 is made of an oxide-containing insulating material (e.g., silicon oxide), a nitride-containing insulating material (e.g., silicon nitride, silicon oxynitride, silicon oxycarbonitride, or silicon carbonitride), an carbon-containing insulating material (e.g., silicon carbide), or a metal oxide material (e.g., aluminum oxide). The mask layers M1 and M2 are made of different materials, in accordance with some embodiments.

In some embodiments, the mask layer M2 is formed by a deposition process, such as a chemical vapor deposition (CVD) process, a low-pressure chemical vapor deposition (LPCVD) process, a plasma enhanced chemical vapor deposition (PECVD) process, a high-density plasma chemical vapor deposition (HDPCVD) process, a spin-on process, or another applicable process.

After the mask layers M1 and M2 are deposited, the mask layer M1 and the overlying mask layer M2 are patterned by a photolithography process and an etching process, so as to expose the portions of the gate electrode material layer.

FIGS. 2A-2F are cross-sectional views of various stages of a process for forming a semiconductor device structure, in accordance with some embodiments. As shown in FIGS. 1 and 2B, a spacer layer 140 is conformally formed over the multilayer stacks 116, the fins 114, the dielectric layer 120, the gate stacks 130, and the mask layers M1 and M2, in accordance with some embodiments.

In some embodiments, as shown in FIG. 2B, the spacer layer 140 is a single-layered structure. In some other embodiments (not shown), the spacer layer 140 is a multi-layered structure. The spacer layer 140 includes layers, in accordance with some embodiments. The layers are made of different materials, in accordance with some embodiments.

In some embodiments, the spacer layer 140 is made of a nitride-containing insulating material or a carbon-containing insulating material, in accordance with some embodiments. The spacer layer 140 is made of silicon nitride (SiN), silicon oxynitride (SiON), silicon oxycarbide (SiOC), silicon oxycarbonitride (SiOCN), or silicon carbonitride (SiCN), in accordance with some embodiments.

The spacer layer 140 is formed using a deposition process, such as a chemical vapor deposition (CVD) process, an atomic layer deposition (ALD) process, or a physical vapor deposition (PVD) process, in accordance with some embodiments.

As shown in FIGS. 1, 2B and 2C, portions of the spacer layer 140 and the multilayer stacks 116, which are not covered by the gate stacks 130 and the spacer layer 140 over the sidewalls of the gate stacks 130, are removed, in accordance with some embodiments. The removed portions of the spacer layer 140 are over top surfaces of the gate stacks 130, the multilayer stacks 116, and the dielectric layer 120, in accordance with some embodiments.

After the removal process, the spacer layer 140 remains over opposite sidewalls of the gate stacks 130 and opposite sidewalls of the mask layers M1 and M2, in accordance with some embodiments. The spacer layer 140 remaining over the opposite sidewalls of the gate stacks 130 and the opposite sidewalls of the mask layers M1 and M2 forms spacers 142, in accordance with some embodiments.

The removal process forms recesses R1 in each multilayer stack 116 and the fin 114 thereunder, in accordance with some embodiments. Each multilayer stack 116 is divided into multilayer stacks 116s by the recesses R1, in accordance with some embodiments. Each multilayer stack 116s includes three layers of the sacrificial layers 116a and three layers of the channel layers 116b, in accordance with some embodiments.

The removal process for forming the recesses R1 includes an etching process, such as an anisotropic etching process (e.g., a dry etching process), in accordance with some embodiments.

As shown in FIG. 2D, portions of the sacrificial layers 116a are removed to form recesses R2 in the multilayer stacks 116s, in accordance with some embodiments. The recess R2 is surrounded by the corresponding sacrificial layer 116a and the corresponding channel layers 116b, in accordance with some embodiments.

The removal process includes an etching process, such as an isotropic etching process (e.g., a dry etching process or a wet etching process), in accordance with some embodiments.

As shown in FIG. 2D, an inner spacer layer 150 is formed in the recesses R2, in accordance with some embodiments. In some embodiments, the inner spacer layer 150 is made of an oxide-containing insulating material, such as silicon oxide.

In some other embodiments, the inner spacer layer 150 is made of a nitride-containing insulating material, such as silicon nitride (SiN), silicon oxynitride (SiON), silicon oxycarbonitride (SiOCN), or silicon carbonitride (SiCN). The inner spacer layer 150 is formed using a deposition process, such as a chemical vapor deposition process or a physical vapor deposition process, in accordance with some embodiments.

As shown in FIG. 2E, epitaxial structures 160 are formed in the recesses R1, in accordance with some embodiments. The epitaxial structures 160 are in direct contact with the fin 114 thereunder, in accordance with some embodiments.

The epitaxial structures 160 are made of a semiconductor material such as silicon or another suitable material, in accordance with some embodiments. The epitaxial structures 160 and the fins 114 (or the substrate 112) are made of the same material, in accordance with some embodiments.

As shown in FIG. 2E, an insulating layer 170 is formed over the epitaxial structures 160 and the substrate 112, in accordance with some embodiments. The insulating layer 170 is used to electrically insulate the epitaxial structures 160 thereunder from source/drain structures formed over the insulating layer 170 in a subsequent process, in accordance with some embodiments. The insulating layer 170 is made of an insulating material such as nitrides (e.g., silicon nitride), in accordance with some embodiments.

As shown in FIG. 2E, source/drain structures 180 are respectively formed in the recesses R1, in accordance with some embodiments. As shown in FIG. 2E, the source/drain structures 180 are over the insulating layer 170 over the epitaxial structures 160, in accordance with some embodiments. Each source/drain structure 180 is in direct contact with the insulating layer 170 thereunder, in accordance with some embodiments.

In some embodiments, the source/drain structures 180 are made of a semiconductor material (e.g., silicon germanium) with P-type dopants, such as the Group IIIA element, in accordance with some embodiments. The Group IIIA element includes boron or another suitable material.

In some other embodiments, the source/drain structures 180 are made of a semiconductor material (e.g., silicon) with N-type dopants, such as the Group VA element, in accordance with some embodiments. The Group VA element includes phosphor (P), antimony (Sb), or another suitable Group VA material. The source/drain structures 180 are formed using an epitaxial process, in accordance with some embodiments.

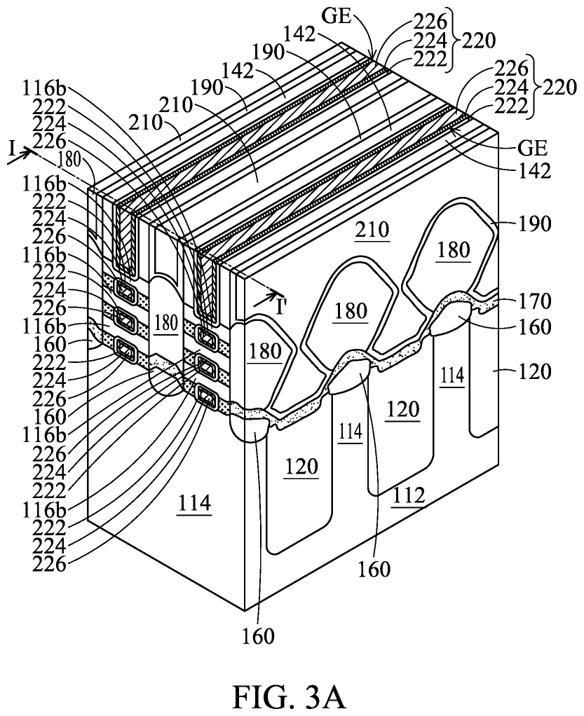

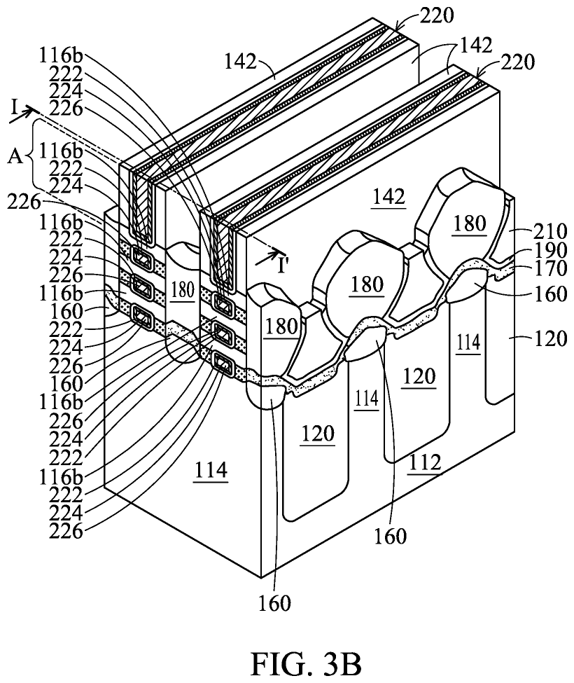

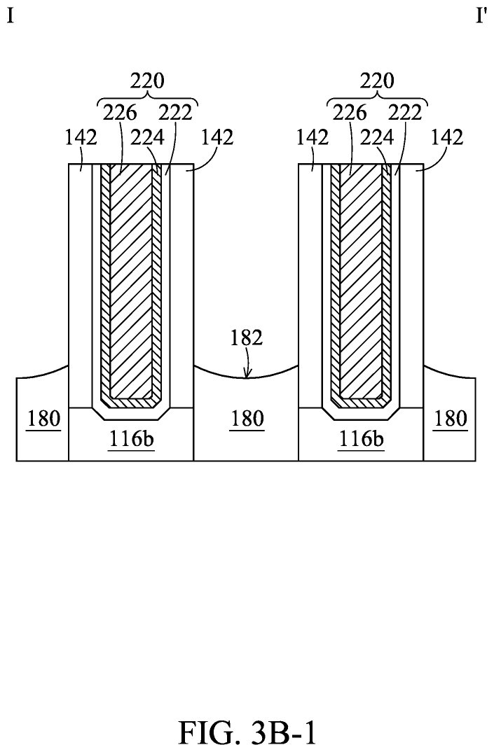

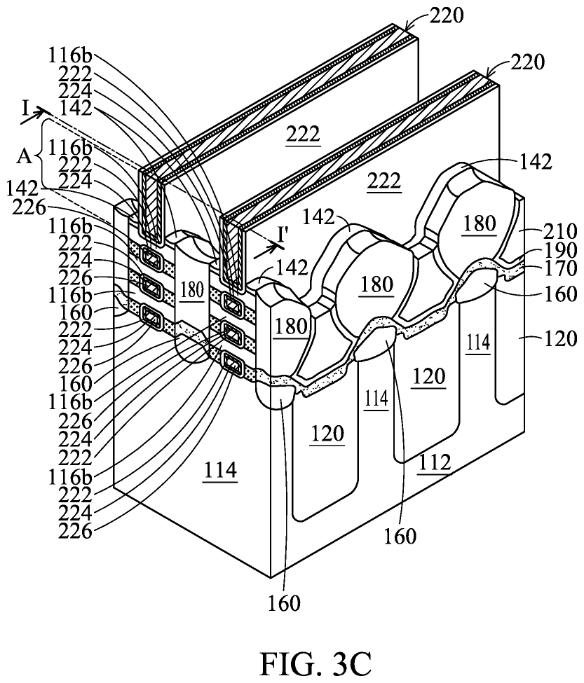

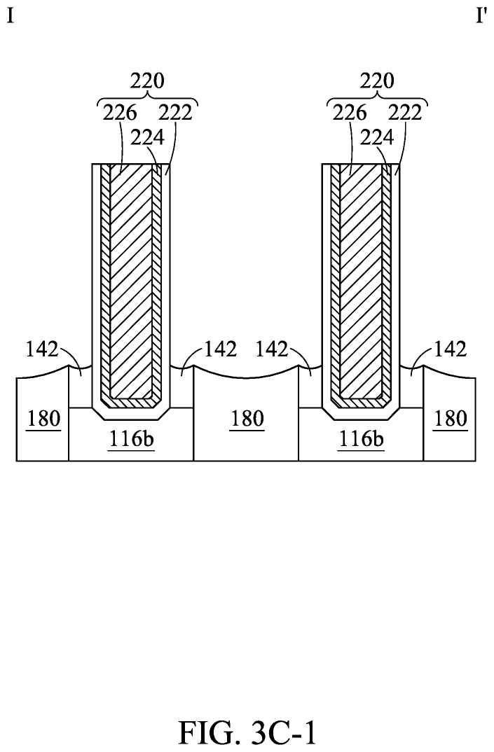

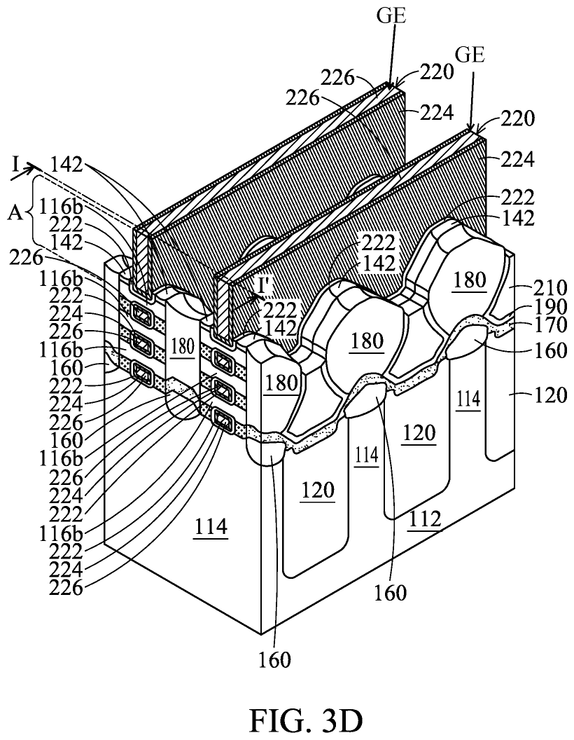

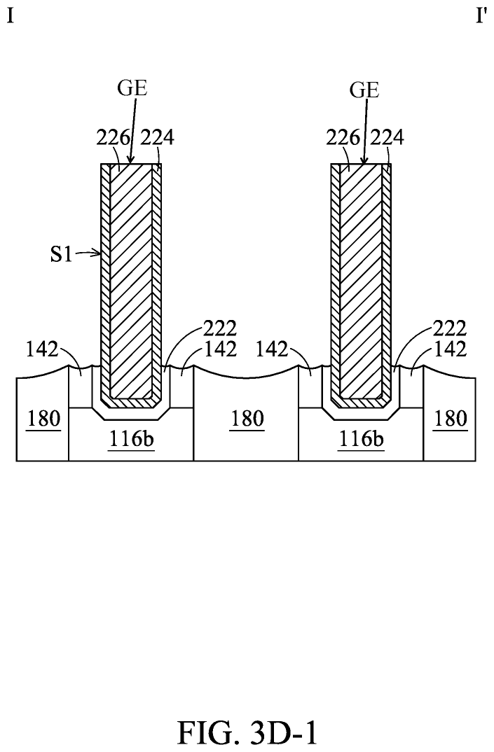

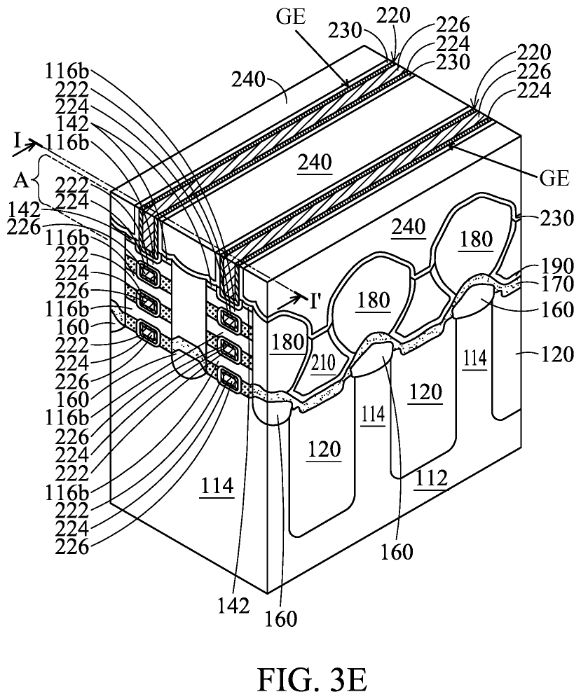

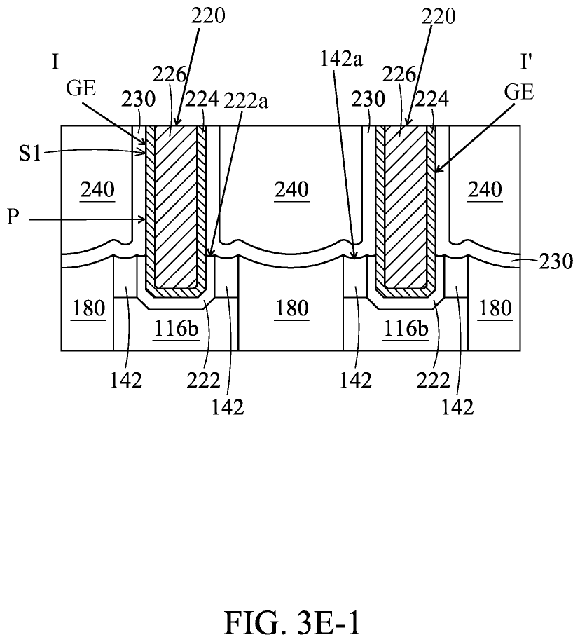

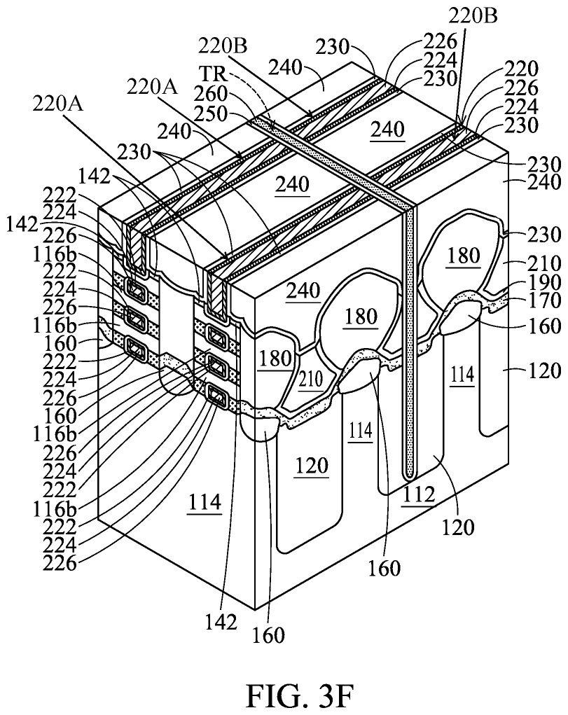

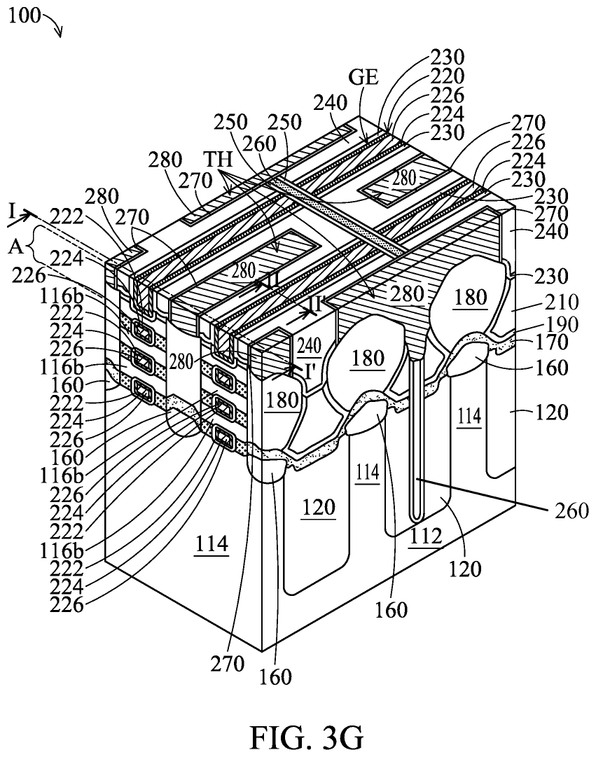

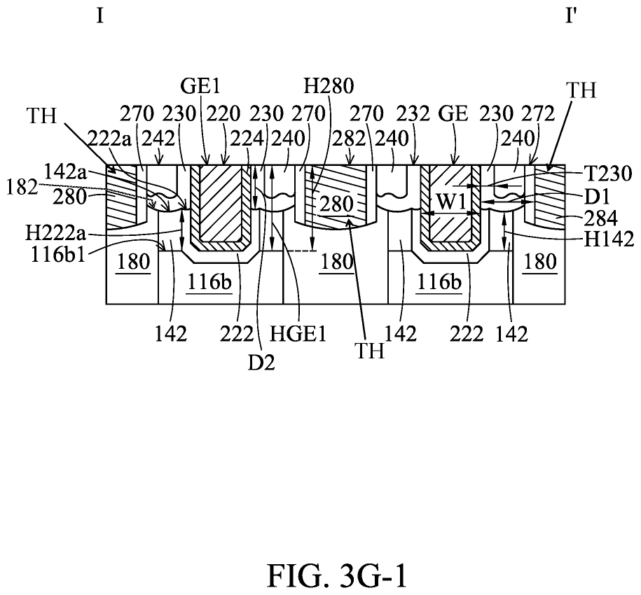

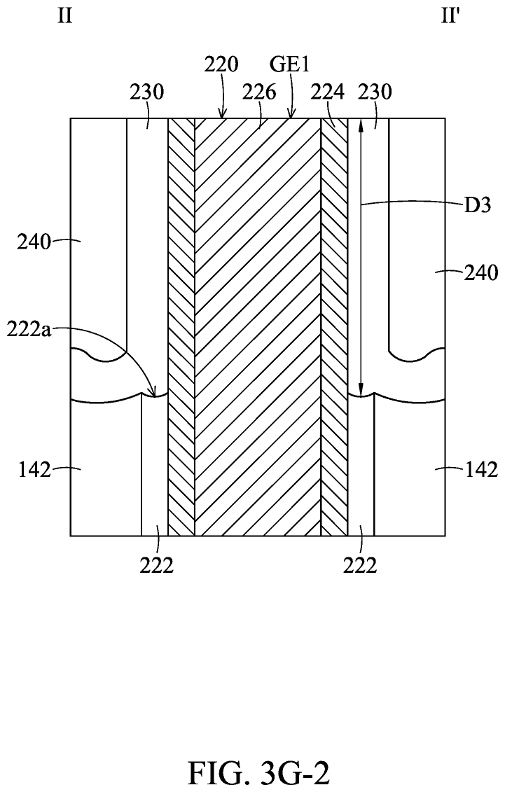

FIG. 3A is a perspective view of the semiconductor device structure of FIG. 2F, in accordance with some embodiments. As shown in FIGS. 2E, 2F and 3A, an etch stop layer 190 is formed over the source/drain structures 180, the spacers 142, and the mask layers M1 and M2, in accordance with some embodiments.

The etch stop layer 190 is made of an insulating material, such as a nitrogen-containing material (e.g., silicon nitride), in accordance with some embodiments. The etch stop layer 190 is formed using a deposition process, such as a chemical vapor deposition (CVD) process, an atomic layer deposition (ALD) process, or a physical vapor deposition (PVD) process, in accordance with some embodiments.

As shown in FIGS. 2F and 3A, a dielectric layer 210 is formed over the etch stop layer 190, in accordance with some embodiments. The dielectric layer 210 and the etch stop layer 190 are made of different materials, in accordance with some embodiments.

The dielectric layer 210 is made of an oxide-containing insulating material, such as silicon oxide, or a nitride-containing insulating material, such as silicon nitride, silicon oxynitride, silicon oxycarbonitride, or silicon carbonitride, in accordance with some embodiments.

The dielectric layer 210 is formed using a deposition process, such as a chemical vapor deposition (CVD) process, an atomic layer deposition (ALD) process, or a physical vapor deposition (PVD) process, in accordance with some embodiments.

As shown in FIGS. 2F and 3A, top portions of the dielectric layer 210, the etch stop layer 190, the spacers 142, the gate stacks 130, and the mask layers M1 and M2 are removed, in accordance with some embodiments. The spacers 142 surround the gate stacks 130 respectively, in accordance with some embodiments. The removal process includes a planarization process, such as a chemical mechanical polishing process, in accordance with some embodiments.

As shown in FIGS. 2E and 2F, the gate electrodes 134 are removed to form trenches 142t in the spacers 142, in accordance with some embodiments. The removal process includes an etching process, such as a wet etching process or a dry etching process, in accordance with some embodiments.

As shown in FIGS. 2E and 2F, the gate dielectric layers 132 are removed through the trenches 142t, in accordance with some embodiments. The removal process includes an etching process, such as a wet etching process or a dry etching process, in accordance with some embodiments.

As shown in FIGS. 2E and 2F, the sacrificial layers 116a are removed through the trenches 142t, in accordance with some embodiments. The removal process includes an etching process, such as a wet etching process or a dry etching process, in accordance with some embodiments.

FIG. 3A is a perspective view of the semiconductor device structure of FIG. 2F, in accordance with some embodiments. FIG. 2F is a cross-sectional view illustrating the semiconductor device structure along a sectional line I-I′ in FIG. 3A, in accordance with some embodiments.

As shown in FIGS. 2F and 3A, gate stacks 220 are formed in the trenches 142t, in accordance with some embodiments. Each gate stack 220 includes a gate dielectric layer 222, a work function layer 224, and a gate electrode layer 226, in accordance with some embodiments.

The work function layer 224 and the gate electrode layer 226 together form a gate electrode GE, in accordance with some embodiments. The gate dielectric layer 222 covers sidewalls S1 and a bottom surface B1 of each gate electrode GE and separates the gate electrode GE from the substrate 112, in accordance with some embodiments.

As shown in FIGS. 2F and 3A, the gate dielectric layer 222, the work function layer 224, and the gate electrode layer 226 are sequentially stacked over the channel layers 116b, in accordance with some embodiments. The gate stack 220 wraps around the channel layers 116b, in accordance with some embodiments.

The inner spacer layer 150 electrically insulates the source/drain structures 180 from the gate stacks 220, in accordance with some embodiments.

FIGS. 3A-3G are perspective views of various stages of a process for forming a semiconductor device structure, in accordance with some embodiments. FIG. 3B-1 is a cross-sectional view illustrating an upper portion A of the semiconductor device structure along a sectional line I-I′ in FIG. 3B, in accordance with some embodiments.

After the step of FIG. 3A, as shown in FIGS. 3B and 3B-1, upper portions of the etch stop layer 190 and the dielectric layer 210 are removed, in accordance with some embodiments. In some embodiments, portions of the source/drain structures 180 are also removed. Therefore, the top surfaces 182 of the source/drain structures 180 become concave curved surfaces, in accordance with some embodiments. The removal process includes an etching process, such as a dry etching process or a wet etching process, in accordance with some embodiments.

FIG. 3C-1 is a cross-sectional view illustrating an upper portion A of the semiconductor device structure along a sectional line I-I′ in FIG. 3C, in accordance with some embodiments. As shown in FIGS. 3C and 3C-1, portions of the spacers 142, which are not between the gate stacks 220 and the source/drain structures 180, are removed, in accordance with some embodiments.

After the spacers 142 are partially removed, portions of the spacers 142 remain between the gate stacks 220 and the source/drain structures 180, in accordance with some embodiments. The removal process includes an etching process, such as an anisotropic etching process (e.g., a dry etching process), in accordance with some embodiments.

FIG. 3D-1 is a cross-sectional view illustrating an upper portion A of the semiconductor device structure along a sectional line I-I′ in FIG. 3D, in accordance with some embodiments. As shown in FIGS. 3D and 3D-1, portions of the gate dielectric layer 222, which are over the sidewalls S1 of the gate electrodes GE and not between the gate electrodes GE and the spacers 142, are removed, in accordance with some embodiments.

After the removal process, lower portions of the gate dielectric layer 222 remain between the gate electrodes GE and the source/drain structures 180 and between the gate electrodes GE and the channel layer 116b, in accordance with some embodiments.

After the removal process, upper portions of the sidewalls S1 of the gate electrodes GE are exposed by the gate dielectric layer 222, in accordance with some embodiments. The removal process includes an etching process, such as an anisotropic etching process (e.g., a dry etching process), in accordance with some embodiments.

FIG. 3E-1 is a cross-sectional view illustrating an upper portion A of the semiconductor device structure along a sectional line I-I′ in FIG. 3E, in accordance with some embodiments. As shown in FIGS. 3E and 3E-1, an etch stop layer 230 is formed over the gate electrodes GE, the source/drain structures 180, the top surfaces 142a of the spacers 142, the top surface 222a of the gate dielectric layer 222, the etch stop layer 190 and the dielectric layer 210, in accordance with some embodiments.

The etch stop layer 230 conformally covers the upper portions P of the sidewalls S1 of the gate electrodes GE, the source/drain structures 180, the top surfaces 142a of the spacers 142, the top surface 222a of the gate dielectric layer 222, the etch stop layer 190 and the dielectric layer 210, in accordance with some embodiments. The etch stop layer 230 is in contact with the upper portions P of the sidewalls S1 of the gate electrodes GE, in accordance with some embodiments.

The etch stop layer 230 is made of an insulating material, such as a nitrogen-containing material (e.g., silicon nitride), in accordance with some embodiments. The etch stop layer 230 is formed using a deposition process, such as a chemical vapor deposition (CVD) process, an atomic layer deposition (ALD) process, or a physical vapor deposition (PVD) process, in accordance with some embodiments.

As shown in FIGS. 3E and 3E-1, a dielectric layer 240 is formed over the etch stop layer 230, in accordance with some embodiments. The gate stacks 220 are embedded in the dielectric layer 240, in accordance with some embodiments. The dielectric layer 240 and the etch stop layer 230 are made of different materials, in accordance with some embodiments.

The dielectric layer 240 is made of an oxide-containing insulating material, such as silicon oxide, or a nitride-containing insulating material, such as silicon nitride, silicon oxynitride, silicon oxycarbonitride, or silicon carbonitride, in accordance with some embodiments.

The dielectric layer 240 is formed using a deposition process, such as a chemical vapor deposition (CVD) process, an atomic layer deposition (ALD) process, or a physical vapor deposition (PVD) process, in accordance with some embodiments.

As shown in FIGS. 3E and 3E-1, upper portions of the dielectric layer 240, the etch stop layer 230, and the gate electrodes GE are removed, in accordance with some embodiments. The removal process includes a planarization process, such as a chemical mechanical polishing process, in accordance with some embodiments.

As shown in FIG. 3F, portions of the dielectric layer 120, the insulating layer 170, the etch stop layer 190, the dielectric layer 210, the gate stacks 220, the etch stop layer 230 and the dielectric layer 240 are removed to form a trench TR passing through the gate stacks 220, in accordance with some embodiments. The gate stack 220 is divided into portions 220A and 220B by the trench TR, in accordance with some embodiments. The portions 220A and 220B are spaced apart from each other, in accordance with some embodiments.

As shown in FIG. 3F, an etch stop layer 250 is formed in the trench TR, in accordance with some embodiments. The etch stop layer 250 conformally covers inner walls of the trench TR, in accordance with some embodiments. The etch stop layer 250 is made of an insulating material, such as a nitrogen-containing material (e.g., silicon nitride), in accordance with some embodiments.

As shown in FIG. 3F, a dielectric layer 260 is formed over the etch stop layer 250, in accordance with some embodiments. The dielectric layer 260 and the etch stop layer 250 are made of different materials, in accordance with some embodiments.

The dielectric layer 260 is made of an oxide-containing insulating material, such as silicon oxide, or a nitride-containing insulating material, such as silicon nitride, silicon oxynitride, silicon oxycarbonitride, or silicon carbonitride, in accordance with some embodiments.

FIG. 3G-1 is a cross-sectional view illustrating an upper portion A of the semiconductor device structure along a sectional line I-I′ in FIG. 3G, in accordance with some embodiments.

As shown in FIGS. 3G and 3G-1, portions of the etch stop layer 190, the dielectric layer 210, the etch stop layer 230, the dielectric layer 240, the etch stop layer 250, and the dielectric layer 260 are removed to form through holes TH, in accordance with some embodiments. The through holes TH pass through the etch stop layer 230 and the dielectric layer 240 to expose portions of the source/drain structures 180, in accordance with some embodiments.

As shown in FIGS. 3G and 3G-1, a liner layer 270 is formed in the through holes TH, in accordance with some embodiments. The liner layer 270 covers inner walls of the through holes TH, in accordance with some embodiments. The liner layer 270 is made of an insulating material, such as a nitrogen-containing material (e.g., silicon nitride), in accordance with some embodiments.

The liner layer 270 is formed using a deposition process and an etching process, in accordance with some embodiments. The deposition process includes a chemical vapor deposition (CVD) process, an atomic layer deposition (ALD) process, or a physical vapor deposition (PVD) process, in accordance with some embodiments. The etching process includes an anisotropic etching process such as a dry etching process, in accordance with some embodiments.

As shown in FIGS. 3G and 3G-1, contact structures 280 are formed in the through holes TH, in accordance with some embodiments. The liner layer 270 wraps around the contact structures 280, in accordance with some embodiments. The liner layer 270 separates the contact structures 280 from the etch stop layer 230 and the dielectric layer 240, in accordance with some embodiments.

The contact structures 280 are in contact with the source/drain structures 180 thereunder, in accordance with some embodiments. The contact structures 280 are partially embedded in the source/drain structures 180 thereunder, in accordance with some embodiments. That is, bottom portions 284 of the contact structures 280 are embedded in the source/drain structures 180 thereunder, in accordance with some embodiments.

The formation of the contact structures 280 includes depositing a conductive layer (not shown) over the gate stacks 220, the etch stop layer 230, the dielectric layer 240, the etch stop layer 250, and the dielectric layer 260 and in the through holes TH; and removing upper portions of the conductive layer, the gate stacks 220, the etch stop layer 230, the dielectric layer 240, the etch stop layer 250, and the dielectric layer 260, in accordance with some embodiments.

After the removal process, the conductive layer remaining in the through holes TH forms the contact structures 280, in accordance with some embodiments. The removal process includes a planarization process, such as a chemical mechanical polishing process, in accordance with some embodiments.

In some embodiments, a top surface 232 of the etch stop layer 230, a top surface 242 of the dielectric layer 240, a top surface 272 of the liner layer 270, a top surface 282 of the contact structure 280, a top surface GE1 of the gate electrode GE are substantially level with each other.

The top surface 222a of the gate dielectric layer 222 and the top surface 142a of the spacer 142 are substantially level with each other, in accordance with some embodiments. The top surface 182 of the source/drain structure 180, the top surface 222a of the gate dielectric layer 222, and the top surface 142a of the spacer 142 are substantially level with each other, in accordance with some embodiments.

The top surface 222a of the gate dielectric layer 222 and the top surface 142a of the spacer 142 are lower than the top surface GE1 of the gate electrode GE, in accordance with some embodiments. The top surface 142a is a concave surface such as a concave curved surface, in accordance with some embodiments. The top surface 222a of the gate dielectric layer 222 is a concave surface such as a concave curved surface, in accordance with some embodiments.

As shown in FIG. 3G-1, a distance D1 between the gate electrode GE and the contact structure 280 ranges from about 5 nm to about 15 nm, in accordance with some embodiments. In some embodiments, a height H280 of the top surface 282 of the contact structure 280 with respect to the top surface 116b1 of the topmost channel layer 116b ranges from about 8 nm to about 30 nm.

In some embodiments, a height HGE1 of the top surface GE1 of the gate electrode GE with respect to the top surface 116b1 of the topmost channel layer 116b ranges from about 5 nm to about 30 nm. In some embodiments, the height HGE1 is substantially equal to the height H280 of the top surface 282 of the contact structure 280.

In some embodiments, the height HGE1 is greater than the height H280 of the top surface 282 of the contact structure 280. In some embodiments, the height HGE1 is less than the height H280 of the top surface 282 of the contact structure 280.

In some embodiments, a height H222a of the top surface 222a of the gate dielectric layer 222 with respect to the top surface 116b1 of the topmost channel layer 116b ranges from about 1 nm to about 10 nm. In some other embodiments, the top surface 222a of the gate dielectric layer 222 is substantially level with the top surface 116b1 of the topmost channel layer 116b.

In some embodiments, a height H142 of the top surface 142a of the spacer 142 with respect to the top surface 116b1 of the topmost channel layer 116b ranges from about 1 nm to about 10 nm. The height H142 is less than or substantially equal to the height H222a, in accordance with some embodiments. In some other embodiments, the spacer 142 is completely removed.

The thickness T230 of the etch stop layer 230 ranges from about 1 nm to about 3 nm, in accordance with some embodiments. In some other embodiments, the etch stop layer 230 is not formed. The width W1 of the gate electrode GE ranges from about 8 nm to about 18 nm, in accordance with some embodiments.

FIG. 3G-2 is a cross-sectional view illustrating an upper portion A of the semiconductor device structure along a sectional line II-II′ in FIG. 3G, in accordance with some embodiments. A distance D3 between the top surface 222a of the gate dielectric layer 222 and the top surface GE1 of the gate electrode GE of FIG. 3G-2 is larger than a distance D2 between the top surface 222a of the gate dielectric layer 222 and the top surface GE1 of the gate electrode GE of FIG. 3G-1, in accordance with some embodiments.

The distance D3 ranges from about 1 nm to about 50 nm, in accordance with some embodiments. In this step, a semiconductor device structure 100 is substantially formed, in accordance with some embodiments.

In the semiconductor device structure 100, the etch stop layer 230 and the dielectric layer 240 electrically insulate the gate electrodes GE from the contact structures 280, in accordance with some embodiments. Since the electrical insulativity of the etch stop layer 230 and the dielectric layer 240 is greater than that of the gate dielectric layer 222, the formation of the etch stop layer 230 and the dielectric layer 240 over the gate dielectric layer 222 reduces the parasitic capacitance between the gate electrodes GE and the contact structures 280, which improves the power efficiency of the semiconductor device structure 100, in accordance with some embodiments.

In the semiconductor device structure 100, the height H280 of the top surface 282 of the contact structure 280 is reduced to be substantially equal to the height HGE1 of the top surface GE1 of the gate electrode GE, and therefore the parasitic capacitance between the contact structures 280 and the gate electrodes GE and between the contact structures 280 and contact structures formed over the gate electrodes GE in the subsequent process is reduced, which improves the power efficiency of the semiconductor device structure 100, in accordance with some embodiments.

In accordance with some embodiments, semiconductor device structures and methods for forming the same are provided. The methods (for forming the semiconductor device structure) form an etch stop layer and a dielectric layer between a gate electrode and a contact structure, which reduces the parasitic capacitance between the gate electrode and the contact structure and therefore improves the power efficiency of the semiconductor device structure.

The methods (for forming the semiconductor device structure) reduce a height of a top surface of a source/drain contact structure to be substantially equal to a height of a top surface of a gate electrode, and therefore the parasitic capacitance between the source/drain contact structure and the gate electrode and between the source/drain contact structure and a gate contact structure over the gate electrode is reduced, which improves the power efficiency of the semiconductor device structure.

In accordance with some embodiments, a method for forming a semiconductor device structure is provided. The method includes forming a gate stack and a source/drain structure over a substrate. The gate stack is adjacent to the source/drain structure, the gate stack includes a gate electrode and a gate dielectric layer, and the gate dielectric layer covers a first sidewall and a bottom surface of the gate electrode and separates the gate electrode from the substrate. The method includes removing the gate dielectric layer over the first sidewall of the gate electrode. The method includes forming a dielectric layer over the source/drain structure and the substrate. The gate stack is embedded in the dielectric layer. The method includes forming a contact structure in the dielectric layer and over the source/drain structure, wherein a first top surface of the contact structure is substantially level with a second top surface of the gate electrode.

In accordance with some embodiments, a method for forming a semiconductor device structure is provided. The method includes forming a gate stack and a source/drain structure over a substrate. The gate stack is adjacent to the source/drain structure, the gate stack includes a gate electrode and a gate dielectric layer, and the gate dielectric layer covers a first sidewall and a bottom surface of the gate electrode. The method includes partially removing the gate dielectric layer over the first sidewall of the gate electrode. The method includes forming an etch stop layer over the source/drain structure, the gate dielectric layer, and the first sidewall of the gate electrode. The etch stop layer is in contact with the first sidewall of the gate electrode. The method includes forming a contact structure passing through the etch stop layer and extending to the source/drain structure. A first top surface of the contact structure is substantially level with a second top surface of the gate electrode.

In accordance with some embodiments, a semiconductor device structure is provided. The semiconductor device structure includes a substrate. The semiconductor device structure includes a gate stack over the substrate. The gate stack includes a gate electrode and a gate dielectric layer, and the gate dielectric layer covers a bottom surface and a lower portion of a sidewall of the gate electrode and separates the gate electrode from the substrate. The semiconductor device structure includes a source/drain structure over the substrate. The gate stack is adjacent to the source/drain structure. The semiconductor device structure includes a dielectric layer over the source/drain structure, the substrate, and a first top surface of the gate dielectric layer. The gate stack is embedded in the dielectric layer. The semiconductor device structure includes a contact structure in the dielectric layer and over the source/drain structure, wherein a second top surface of the contact structure, a third top surface of the gate electrode, and a fourth top surface of the dielectric layer are substantially level with each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a gate stack and a source/drain structure over a substrate, wherein the gate stack is adjacent to the source/drain structure, the gate stack comprises a gate electrode and a gate dielectric layer, and the gate dielectric layer covers a first sidewall and a bottom surface of the gate electrode and separates the gate electrode from the substrate;
removing the gate dielectric layer over the first sidewall of the gate electrode;
forming a dielectric layer over the source/drain structure and the substrate, wherein the gate stack is embedded in the dielectric layer; and
forming a contact structure in the dielectric layer and over the source/drain structure, wherein a first top surface of the contact structure is substantially level with a second top surface of the gate electrode.

2. The method for forming the semiconductor device structure as claimed in claim 1, wherein an upper portion of the first sidewall of the gate electrode is exposed by the gate dielectric layer after the gate dielectric layer over the first sidewall of the gate electrode is removed.

3. The method for forming the semiconductor device structure as claimed in claim 1, further comprising:
forming an etch stop layer over the first sidewall of the gate electrode, the source/drain structure, and the substrate after the gate dielectric layer over the first sidewall of the gate electrode is removed and before the dielectric layer is formed over the source/drain structure and the substrate, wherein the dielectric layer is formed over the etch stop layer.

4. The method for forming the semiconductor device structure as claimed in claim 3, wherein the etch stop layer is in contact with the first sidewall of the gate electrode.

5. The method for forming the semiconductor device structure as claimed in claim 3, wherein the first top surface of the contact structure is substantially level with a third top surface of the etch stop layer.

6. The method for forming the semiconductor device structure as claimed in claim 1, wherein the first top surface of the contact structure is substantially level with a third top surface of the dielectric layer.

7. The method for forming the semiconductor device structure as claimed in claim 1, further comprising:
forming a liner layer in the dielectric layer, wherein the liner layer wraps around the contact structure and separates the contact structure from the dielectric layer.

8. The method for forming the semiconductor device structure as claimed in claim 1, further comprising:
forming a spacer over the substrate before the gate stack and the source/drain structure are formed, wherein the spacer covers a second sidewall of the gate stack, and
the method further comprises:
partially removing the spacer before the gate dielectric layer over the first sidewall of the gate electrode is removed.

9. The method for forming the semiconductor device structure as claimed in claim 8, wherein a portion of the spacer remains between the gate stack and the source/drain structure after the spacer is partially removed.

10. The method for forming the semiconductor device structure as claimed in claim 1, wherein a portion of the gate dielectric layer remains between the gate electrode and the source/drain structure after the gate dielectric layer over the first sidewall of the gate electrode is removed.

11. A method for forming a semiconductor device structure, comprising:
forming a gate stack and a source/drain structure over a substrate, wherein the gate stack is adjacent to the source/drain structure, the gate stack comprises a gate electrode and a gate dielectric layer, and the gate dielectric layer covers a sidewall and a bottom surface of the gate electrode;
partially removing the gate dielectric layer over the sidewall of the gate electrode;
forming an etch stop layer over the source/drain structure, the gate dielectric layer, and the sidewall of the gate electrode, wherein the etch stop layer is in contact with the sidewall of the gate electrode; and
forming a contact structure passing through the etch stop layer and extending to the source/drain structure, wherein a first top surface of the contact structure is substantially level with a second top surface of the gate electrode.

12. The method for forming the semiconductor device structure as claimed in claim 11, further comprising:
forming a liner layer passing through the etch stop layer and extending to the source/drain structure before the contact structure is formed, wherein the liner layer surrounds the contact structure.

13. The method for forming the semiconductor device structure as claimed in claim 12, wherein the second top surface of the gate electrode is substantially level with a third top surface of the liner layer.

14. The method for forming the semiconductor device structure as claimed in claim 11, wherein the contact structure is partially embedded in the source/drain structure.

15. The method for forming the semiconductor device structure as claimed in claim 11, wherein a portion of the gate dielectric layer remains between the gate electrode and the source/drain structure after the gate dielectric layer over the sidewall of the gate electrode is partially removed.

16. A semiconductor device structure, comprising:
a substrate;
a gate stack over the substrate, wherein the gate stack comprises a gate electrode and a gate dielectric layer, and the gate dielectric layer covers a bottom surface and a lower portion of a sidewall of the gate electrode and separates the gate electrode from the substrate;
a source/drain structure over the substrate, wherein the gate stack is adjacent to the source/drain structure;
a dielectric layer over the source/drain structure, the substrate, and a first top surface of the gate dielectric layer, wherein the gate stack is embedded in the dielectric layer; and
a contact structure in the dielectric layer and over the source/drain structure, wherein a second top surface of the contact structure, a third top surface of the gate electrode, and a fourth top surface of the dielectric layer are substantially level with each other.

17. The semiconductor device structure as claimed in claim 16, further comprising:
an etch stop layer over an upper portion of the sidewall of the gate electrode, the first top surface of the gate dielectric layer, and the source/drain structure, wherein the dielectric layer is over the etch stop layer.

18. The semiconductor device structure as claimed in claim 17, wherein the etch stop layer is in contact with the upper portion of the sidewall of the gate electrode.

19. The semiconductor device structure as claimed in claim 16, further comprising:
a spacer surrounding the gate dielectric layer, wherein the first top surface of the gate dielectric layer and a fifth top surface of the spacer are lower than the third top surface of the gate electrode.

20. The semiconductor device structure as claimed in claim 16, wherein the first top surface of the gate dielectric layer is a concave surface.
